(19) United States
(12) Patent Application Publication
(10) Pub. No.: US 2024/0113050 A1
(43) Pub. Date: Apr. 4, 2024

(54) SEMICONDUCTOR PACKAGES WITH DIRECTIONAL ANTENNAS

(71) Applicant: TEXAS INSTRUMENTS INCORPORATED, Dallas, TX (US)

(72) Inventors: Juan HERBSOMMER, Allen, TX (US); Yiqi TANG, Allen, TX (US); Rajen Manicon MURUGAN, Dallas, TX (US)

(21) Appl. No.: 17/956,798

(22) Filed: Sep. 29, 2022

(51) Int. Cl. H01L 23/66; H01Q 1/22; H01Q 13/02

(52) U.S. Cl. CPC H01L 23/66; H01Q 1/2283; H01Q 13/02; H01L 2223/6627; H01L 2223/6677

(57) ABSTRACT

In some examples, a semiconductor package includes a semiconductor die; a conductive member coupled to the semiconductor die; and a multi-layer package substrate. The multi-layer package substrate includes a first horizontal metal layer to provide a ground connection; a second horizontal metal layer above the first horizontal metal layer; vertical members coupling to the first and second horizontal metal layers; and a mold compound covering the first and second horizontal metal layers and the vertical members. The first horizontal metal layer, the second horizontal metal layer, and the vertical members together form a structure including a conductive strip coupled to the conductive member, a transition member coupled to the conductive strip, a waveguide coupled to the transition member, and a horn antenna coupled to the waveguide.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique. One such technique is the “flip-chip” technique, in which the semiconductor chip (also called a “die”) is oriented so the device side of the chip (in which circuitry is formed) is facing downward. The device side is coupled to the conductive terminals using, e.g., solder bumps. Another technique is the wirebonding technique, in which the device side of the semiconductor chip is oriented upward and is coupled to the conductive terminals using bond wires. Wirebonds are formed on bond pads, which are positioned on semiconductor dies and provide interfaces between the wirebonds and circuitry of the semiconductor dies.

### SUMMARY

In some examples, a semiconductor package includes a semiconductor die; a conductive member coupled to the semiconductor die; and a multi-layer package substrate. The multi-layer package substrate includes a first horizontal metal layer to provide a ground connection; a second horizontal metal layer above the first horizontal metal layer; vertical members coupling to the first and second horizontal metal layers; and a mold compound covering the first and second horizontal metal layers and the vertical members. The first horizontal metal layer, the second horizontal metal layer, and the vertical members together form a structure including a conductive strip coupled to the conductive member, a transition member coupled to the conductive strip, a waveguide coupled to the transition member, and a horn antenna coupled to the waveguide.

In some examples, a method for manufacturing a semiconductor package comprises forming a multi-layer package substrate by plating a first horizontal metal ground layer on a carrier; plating multiple vertical members on the first horizontal metal ground layer; applying a first mold compound to the first horizontal metal ground layer and the multiple vertical members; grinding the mold compound and at least part of the multiple vertical members; plating a second horizontal metal layer on the multiple vertical members; applying a second mold compound to the second horizontal metal layer; and grinding the second mold compound and at least part of the second horizontal metal layer. The method includes coupling a semiconductor die to the second horizontal metal layer applying a third mold compound to the second mold compound and the semiconductor die. The first horizontal metal ground layer, the multiple vertical members, and the second horizontal metal layer form a structure that includes a conductive strip coupled to the semiconductor die and multiple impedance-matched components of differing shapes configured to guide electromagnetic waves in a predetermined direction.

### BRIEF DESCRIPTION OF THE DRAWINGS

FIG. 1A is a perspective view of a molded semiconductor package having a directional antenna and efficient signal path included therein, in accordance with various examples.

FIG. 1B is a frontal view of a molded semiconductor package having a directional antenna and efficient signal path included therein, in accordance with various examples.

FIG. 1C is a profile cross-sectional view of a molded semiconductor package having a directional antenna and efficient signal path included therein, in accordance with various examples.

FIG. 1D is a top-down view of a molded semiconductor package having a directional antenna and efficient signal path included therein, in accordance with various examples.

FIG. 2A is a perspective view of a molded semiconductor package having a directional antenna and efficient signal path included therein, in accordance with various examples.

FIG. 2B is a frontal view of a molded semiconductor package having a directional antenna and efficient signal path included therein, in accordance with various examples.

FIG. 2C is a profile view of a molded semiconductor package having a directional antenna and efficient signal path included therein, in accordance with various examples.

FIG. 2D is a top-down, see-through view of a molded semiconductor package having a directional antenna and efficient signal path included therein, in accordance with various examples.

FIG. 2E is a perspective view of a molded semiconductor package having a directional antenna and efficient signal path included therein, in accordance with various examples.

FIG. 2F is a profile view of a molded semiconductor package having a directional antenna and efficient signal path included therein, in accordance with various examples.

FIG. 3 is a graph depicting the efficiency of a molded semiconductor package having a directional antenna and efficient signal path included therein, in accordance with various examples.

FIG. 4 is a perspective view of an electric field diagram depicting the efficiency of a molded semiconductor package having a directional antenna and efficient signal path included therein, in accordance with various examples.

FIG. 5 is a profile view of an electric field diagram depicting the efficiency of a molded semiconductor package having a directional antenna and efficient signal path included therein, in accordance with various examples.

FIG. 6 is a schematic diagram depicting the directionality of an antenna in a molded semiconductor package, in accordance with various examples.

FIG. 7A is a perspective view of a molded semiconductor package having a directional antenna, efficient signal path, and grounded coplanar waveguide included therein, in accordance with various examples.

FIG. 7B is a frontal view of a molded semiconductor package having a directional antenna, efficient signal path, and grounded coplanar waveguide included therein, in accordance with various examples.

FIG. 7C is a profile cross-sectional view of a molded semiconductor package having a directional antenna, efficient signal path, and grounded coplanar waveguide included therein, in accordance with various examples.

FIG. 7D is a top-down, see-through view of a molded semiconductor package having a directional antenna, efficient signal path, and grounded coplanar waveguide included therein, in accordance with various examples.

FIG. 8A is a perspective view of a molded semiconductor package having a directional antenna, efficient signal path, and grounded coplanar waveguide included therein, in accordance with various examples.

FIG. 8B is a frontal view of a molded semiconductor package having a directional antenna, efficient signal path, and grounded coplanar waveguide included therein, in accordance with various examples.

FIG. 8C is a profile cross-sectional view of a molded semiconductor package having a directional antenna, efficient signal path, and grounded coplanar waveguide included therein, in accordance with various examples.

FIG. 8D is a top-down, see-through view of a molded semiconductor package having a directional antenna, efficient signal path, and grounded coplanar waveguide included therein, in accordance with various examples.

FIG. 9 is a graph depicting the efficiency of a molded semiconductor package having a directional antenna, efficient signal path, and grounded coplanar waveguide included therein, in accordance with various examples.

FIG. 10 is a perspective view of an electric field diagram depicting the efficiency of a molded semiconductor package having a directional antenna, efficient signal path, and grounded coplanar waveguide included therein, in accordance with various examples.

FIG. 11 is a perspective view of an electric field diagram depicting the efficiency of a molded semiconductor package having a directional antenna, efficient signal path, and grounded coplanar waveguide included therein, in accordance with various examples.

FIG. 12 is a schematic diagram depicting the directionality of an antenna in a molded semiconductor package, in accordance with various examples.

FIGS. 13A and 13B are a process flow diagram of a method for manufacturing a semiconductor package having a directional antenna and efficient signal path included therein, in accordance with various examples.

FIG. 14 is a flow diagram of a method for manufacturing a semiconductor package having a directional antenna and efficient signal path include therein, in accordance with various examples.

### DETAILED DESCRIPTION

Some types of semiconductor packages include circuitry for wireless applications. For example, a semiconductor package used in wireless applications may include a semiconductor die having radio frequency (RF) circuitry formed on a device side of the die, and such circuitry may be coupled to an antenna that is included in the package. In some wireless applications, such as radar, 5G, and other high-frequency applications, it is difficult to achieve an efficient, low-loss signal path between the semiconductor die and the antenna. This challenge is exacerbated in the context of high directivity antennas that are integrated into semiconductor packages, and the challenge is made even greater in mold compound encapsulated packages.

This disclosure describes various examples of a molded semiconductor package, such as a quad flat no lead (QFN) package, that mitigates the challenges described above. Specifically, the molded semiconductor package described herein includes a directional antenna integrated with the package. The package includes an efficient, low loss signal path between the antenna and a semiconductor die of the package. The signal path and the antenna are formed in a multi-layer package substrate that includes a first horizontal plated metal layer to provide a ground connection, a second horizontal plated metal layer above the first plated metal layer, plated vertical members coupling to the first and second horizontal plated metal layers, and a mold compound abutting the first and second horizontal plated metal layers and the plated vertical members. The first horizontal plated metal layer forms a conductive strip coupled to the conductive member and configured to guide an electromagnetic wave away from the conductive member. The first and second horizontal plated metal layers and the plated vertical members form a transition member coupled to the conductive strip, having a flared shape, and configured to guide the electromagnetic wave away from the conductive strip. The first and second horizontal plated metal layers and the plated vertical members form a waveguide coupled to the transition member, having a rectangular prism shape, and configured to guide the electromagnetic wave away from the transition member. The first and second horizontal plated metal layers and the plated vertical members form a horn antenna coupled to the waveguide and configured to direct the electromagnetic wave from the waveguide to a predetermined direction.

By using electroplating techniques as described below to form the metallic structures in the package, undesirable gaps that would otherwise be present between individual members composing such metallic structures (e.g., vias not in contact with each other) would permit energy to escape, thereby considerably reducing efficiency. Efficiency is further improved by designing consecutive metallic structures in the package that are impedance matched such that electromagnetic (EM) waves propagating across a structural boundary are maximally transferred across the boundary and are minimally reflected backward and away from the boundary. Further, as described in greater detail below, the metallic structures are oriented to produce high directivity, meaning that EM (e.g., RF) waves are emitted in a specific direction. The package is also well-suited to accommodating high frequencies (e.g., 400 MHz to 52 GHz), because at these ranges of frequencies the antenna can be integrated in the package. This is because the antenna must have approximately the size of the wavelength of the EM waves in the mold compound environment (a high dielectric constant). At this frequency range (e.g., 400 MHz to 52 GHz), the wavelength is smaller than the size of the package (lower than 100 mm²), which allows the antenna to be integrated in the package. Thus, the package is useful in high-frequency applications, such as radar (400 MHz to 36 GHz) and 5G (450 MHz to 52 GHz).

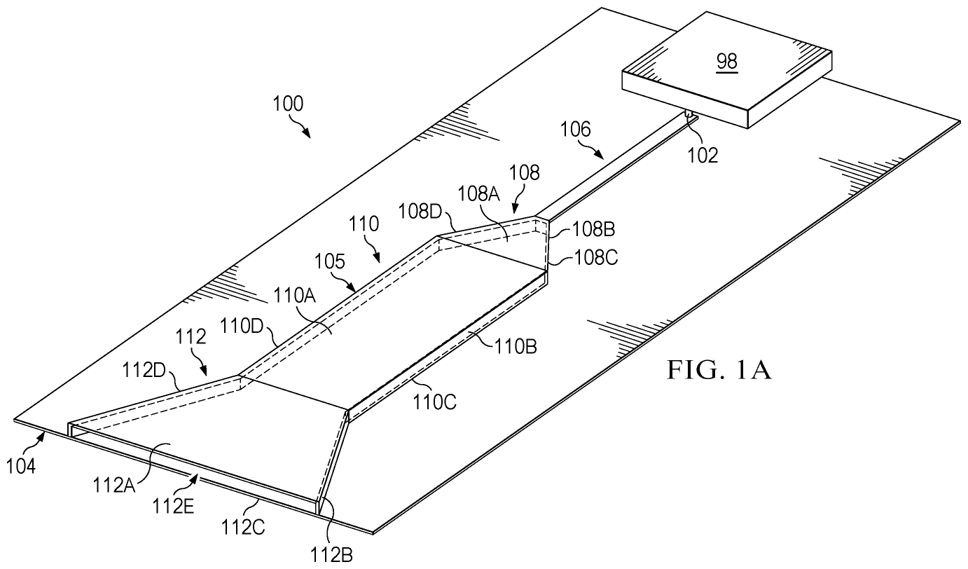

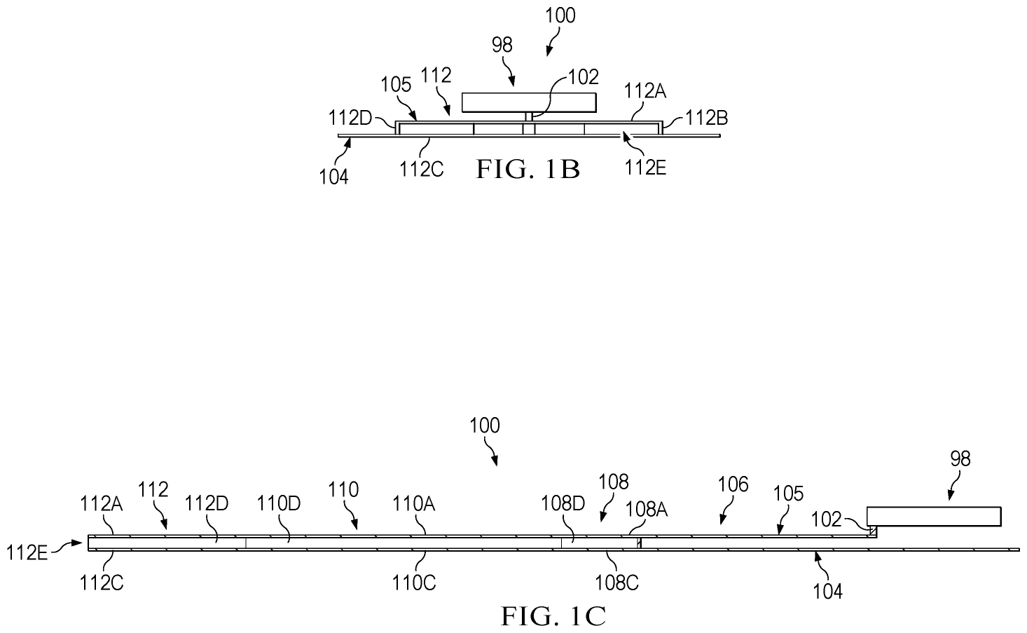

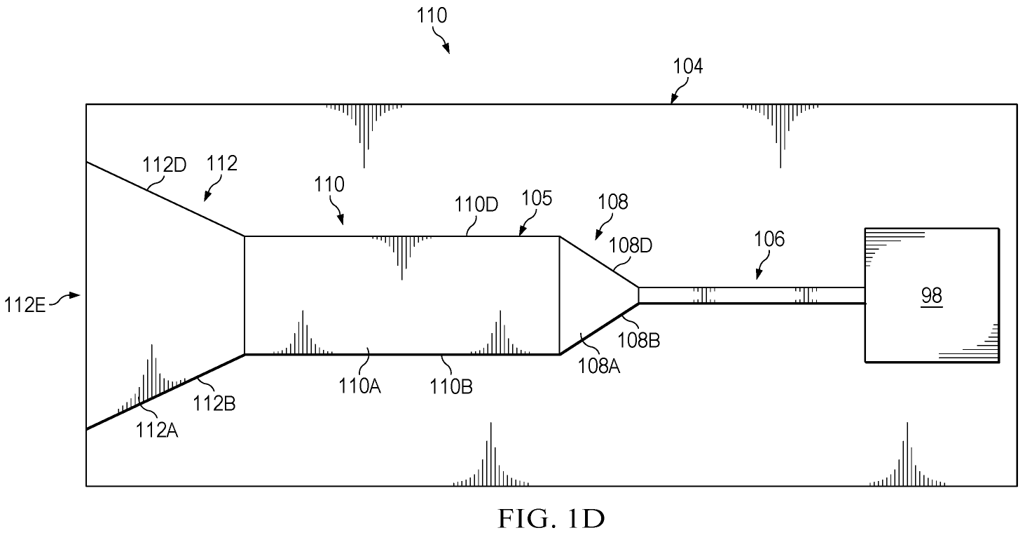

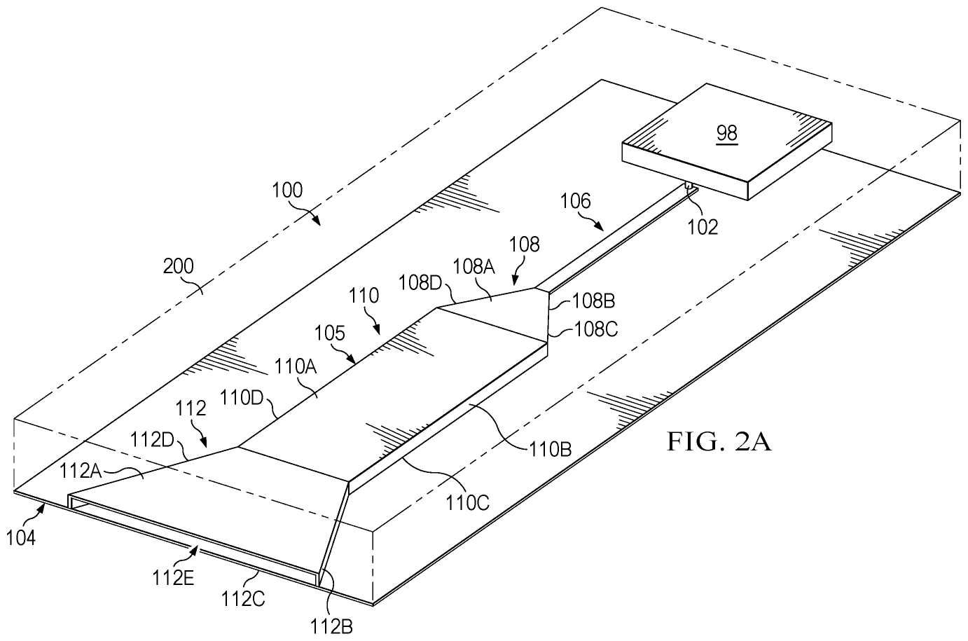

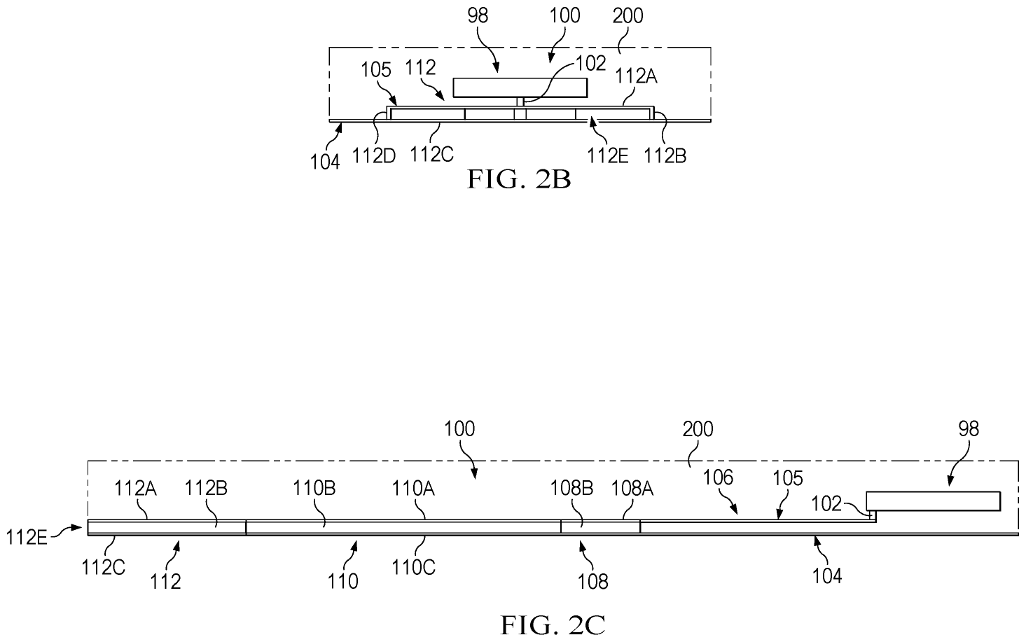

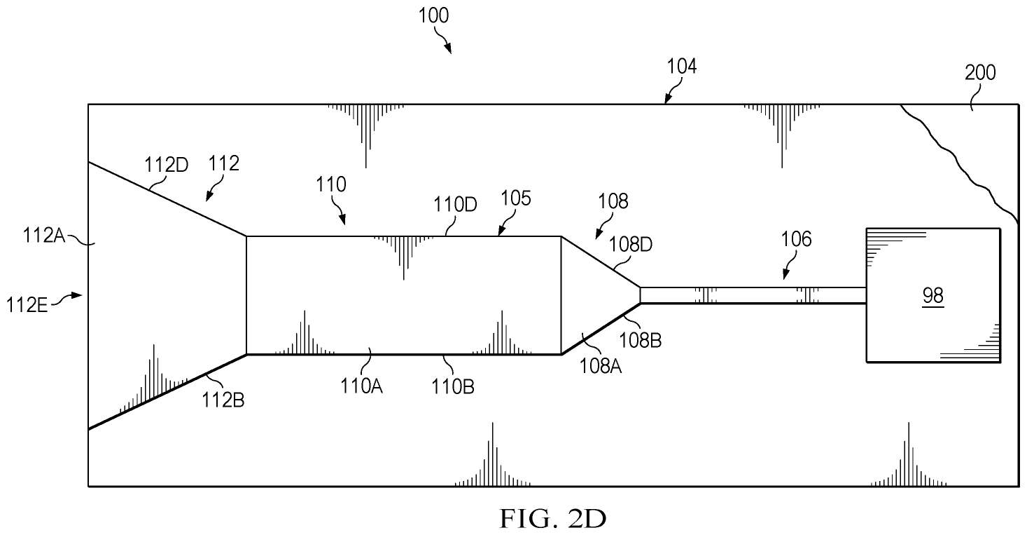

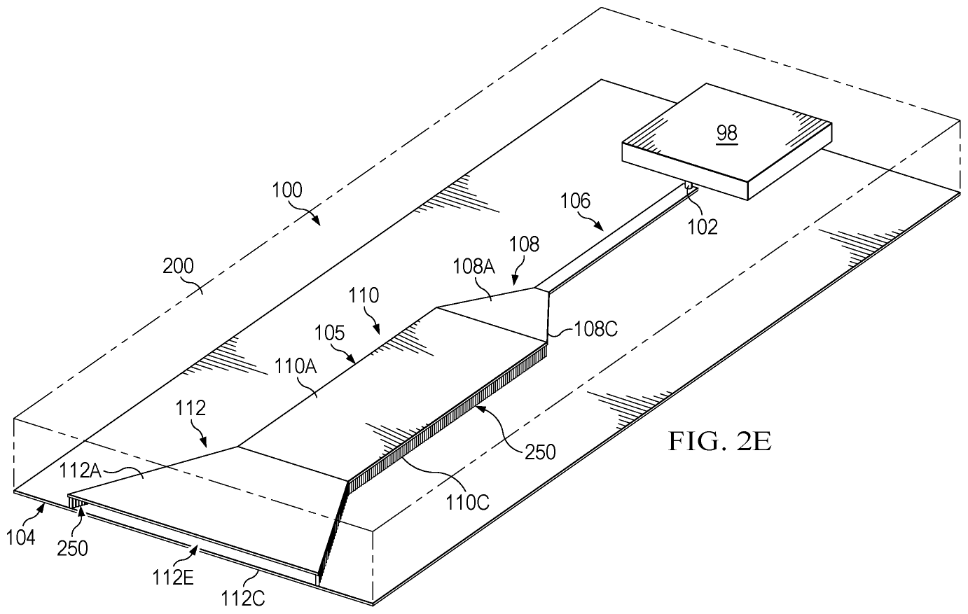

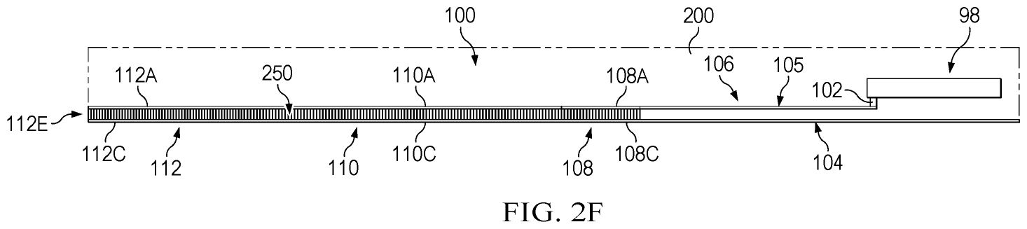

FIG. 1A is a perspective view of a molded semiconductor package having a directional antenna and efficient signal path included therein, in accordance with various examples. The semiconductor package 100 comprises a semiconductor die 98, a conductive member 102, a first horizontal metal layer 104, a conductive strip 106, a transition member 108, a waveguide 110, and a horn antenna 112. The semiconductor die 98 includes circuitry configured to perform any suitable function, for example, to process signals to be transmitted via the horn antenna 112 and/or to process signals that are received via the horn antenna 112. The semiconductor die 98 is positioned above the first horizontal metal layer 104 and is supported by a mold compound (shown in FIGS. 2A-2D). In examples, a device side of the semiconductor die 98 on and in which the aforementioned circuitry is formed faces downward, toward the first horizontal metal layer 104.

The first horizontal metal layer 104 comprises a metal, such as copper, nickel, aluminum, or gold, and is coupled to a ground connection, such as on a printed circuit board (PCB) or other structure to which the semiconductor package 100 may be coupled. Accordingly, the first horizontal metal layer 104 functions as a ground plane. The first horizontal metal layer 104 forms the bottom surfaces for the transition member 108, the waveguide 110, and the horn antenna 112, and, as shown, the first horizontal metal layer 104 also extends horizontally beyond the transition member 108, the waveguide 110, and the horn antenna 112. A second horizontal metal layer 105 forms the top surfaces for the conductive strip 106, the transition member 108, the waveguide 110, and the horn antenna 112. Unlike the first horizontal metal layer 104, the second horizontal metal layer 105 does not extend horizontally beyond the conductive strip 106, the transition member 108, the waveguide 110, and the horn antenna 112.

The conductive strip 106 is a transmission line configured to provide signals to and from the circuitry of the semiconductor die 98. The conductive strip 106 is defined as a conductor that is separated from the first horizontal metal layer 104 (the ground plane) by a dielectric, such as mold compound positioned between the conductive strip 106 and the first horizontal metal layer 104. In some examples, this dielectric may be a material other than a mold compound, such as air. The conductive strip 106 is formed by the second horizontal metal layer 105. Because the conductive strip 106 is thin relative to the other components of the semiconductor package 100 shown in FIG. 1A, the second horizontal metal layer 105 is adequate to form the entire vertical thickness of the conductive strip 106. The conductive strip 106 is coupled to the circuitry of the semiconductor die 98 by way of the conductive member 102 (e.g., a copper pillar).

The transition member 108 is coupled to an end of the conductive strip 106 distal to the semiconductor die 98. A transition member is defined as a flared metal waveguide to confine and convey EM waves. The transition member 108 has a top surface 108A formed by the second horizontal metal layer 105 and a bottom surface 108C formed by the first horizontal metal layer 104. Further, the transition member 108 has vertical members 108B and 108D that extend between and couple the top and bottom surfaces 108A, 108C to each other. In examples, the vertical members 108B, 108D are electroplated and have approximately uniform thickness throughout. In examples, the vertical members 108B, 108D are composed of a set of vias in close proximity to each other (e.g., touching each other such that each via is in contact with at least one other via), and such vias may be formed using any suitable technique, including electroplating. In examples, the top and bottom surfaces 108A, 108C and the vertical members 108B, 108D are composed of copper, nickel, aluminum, gold, or another suitable metal or alloy. The transition member 108 has a flared shape, meaning that the vertical cross-sectional area of the transition member 108 increases along the length of the transition member 108 from the conductive strip 106 to the waveguide 110. The transition member 108 has a horizontal cross-sectional area that is approximately equal throughout its thickness. The transition member 108 is useful to provide a gradual and even transition from the conductive strip 106 to the waveguide 110 such that EM signals (waves) and thus properly match the impedances of the conductive strip 106 and the waveguide 110. If this gradual tapering were not introduced, for example, as a result of an unacceptably sharp or uneven gradient between the conductive strip 106 to the waveguide 110, the abrupt change of impedances would create a severe EM wave reflection (technically known as a poor return loss). This effect would be detrimental to the efficient propagation of the signal between the semiconductor die 98 to the horn antenna 112.

The waveguide 110 is coupled to the end of the transition member 108 distal to the semiconductor die 98. A waveguide is defined as a metal tube confining and conveying EM waves. The waveguide 110 has a vertical cross-sectional area that is approximately equal throughout its length. The waveguide 110 has a horizontal cross-sectional area that is approximately equal throughout its thickness. The waveguide 110 may be a rectangular prism, for example. A top surface 110A of the waveguide 110 is formed by the second horizontal metal layer 105, and a bottom surface 110C of the waveguide 110 is formed by the first horizontal metal layer 104. The waveguide 110 includes vertical members 110B and 110D that extend between and couple the top surfaces 110A, 110C to each other. In examples, the vertical members 110B, 110D are electroplated and have approximately uniform thickness throughout. In examples, the vertical members 110B, 110D are composed of a set of vias in close proximity to each other (e.g., touching each other such that each via is in contact with at least one other via), and such vias may be formed using any suitable technique, including electroplating. In examples, the top and bottom surfaces 110A, 110C and the vertical members 110B, 110D are composed of copper, aluminum, nickel, gold, or another suitable metal or alloy.

A horn antenna is defined as a flaring metal waveguide to direct EM waves in a beam. The horn antenna 112 has a flared shape, with the smallest vertical cross-sectional area of the horn antenna 112 coupled to the distal end of the waveguide 110, and the largest vertical cross-sectional area of the horn antenna 112 flush or approximately flush with an edge 113 of the first horizontal metal layer 104. The horizontal cross-sectional area of the horn antenna 112 is approximately uniform throughout the thickness of the horn antenna 112. In examples, the distal end of the horn antenna 112 is flush or approximately flush with a side surface of the semiconductor package 100 (shown in FIGS. 2A-2D). The horn antenna 112 has a top surface 112A that is formed by the second horizontal metal layer 105, and a bottom surface 112C that is formed by the first horizontal metal layer 104. Vertical members 112B, 112D extend between and couple the first and second horizontal metal layers 104, 105 to each other. The horn antenna 112 is useful to provide a gradual and even transition from the waveguide 110 to an exterior of the semiconductor package 100 such that EM signals (waves) do not experience a severe reflection (return loss) that would otherwise be introduced into the EM signals, for example, as a result of an unacceptably sharp or uneven gradient between the waveguide 110 and the exterior of the semiconductor package 100. The horn antenna 112 terminates at a distal end having an orifice 112E.

As described above, consecutive metallic structures in the semiconductor package 100 are impedance matched such that EM waves propagating across a structural boundary are maximally transferred across the boundary and are minimally reflected backward and away from the boundary. More specifically, the sequence of consecutive metallic structures in the semiconductor package 100 includes the conductive member 102, the conductive strip 106, the transition member 108, the waveguide 110, and the horn antenna 112. Other sequences of these structures, the substitution of structures, the removal of structures, and/or the addition of different structures are all contemplated and included in the scope of this disclosure. The conductive member 102 should be impedance matched with the conductive strip 106, which, in turn, should be impedance matched with the transition member 108, which, in turn, should be impedance matched with the waveguide 110, which, in turn, should be impedance matched with the horn antenna 112, which, in turn, should be impedance matched with the free space surrounding the semiconductor package 100. Failure to properly impedance match any consecutive structures in this sequence can introduce inefficiencies due to increased reflection and/or decreased transfer of waves across the boundary between any two structures, or between the horn antenna 112 and surrounding free space. More specifically, an impedance gradient between first and second consecutive, impedance-mismatched structures in the semiconductor package 100 causes an EM wave to be at least partially reflected backward toward the source of the EM wave. The reflected EM waves cause standing EM waves in the first structure, wasting energy and increasing the standing wave ratio (SWR).

Impedance matching of consecutive structures between the conductive member 102 and the free space surrounding the semiconductor package 100 may be achieved by controlling various properties of these structures, including shape, size (e.g., vertical cross-sectional size), material composition, and structural wall thickness, the most effective ways to manipulate impedance is by controlling the shape and size of each structure. For example, the conductive member 102 may have an impedance of 50 ohms, and the physical properties of the conductive strip 106 may be controlled to produce an impedance of 50 ohms as well. Thus, EM signals propagating from the conductive member 102 to the conductive strip 106 will have low or no reflection backward toward the conductive member 102. The vertical cross-sectional thickness of the conductive strip 106 can be manipulated to control the impedance of the conductive strip 106, thereby producing an example impedance of 50 ohms.

Not every structure shown in FIGS. 1A-1D has a consistent impedance throughout its length. For example, a second structure that consecutively follows a first structure and that consecutively precedes a third structure should have a consistent impedance throughout its length only if the first and third structures have the same impedance. For instance, if the first and third structures have impedances of 50 ohms, the second structure may also have a consistent impedance of 50 ohms along its entire length. However, if the first and third structures have differing impedances, then the second structure positioned between the first and third structures should have a gradual impedance gradient. For example, if the conductive strip 106 has an impedance of 50 ohms and the waveguide 110 has an impedance of 200 ohms, the transition member 108 should have an impedance that gradually transitions from 50 ohms (at the point of connection with the conductive strip 106) to 200 ohms (at the point of connection with the waveguide 110). An impedance gradient in the transition member 108 that is too large will precipitate the signal reflection-induced inefficiencies described above.

To achieve the gradual impedance gradient in the transition member 108 described above, the transition member 108 has a flared shape, meaning that the transition member 108 has a smaller vertical cross-sectional area at the point of connection with the conductive strip 106 and a larger vertical cross-sectional area at the point of connection with the waveguide 110, with an even taper therebetween. An excessively abrupt or steep taper is unacceptable because of the impedance gradient (and, thus, inefficiency) it would introduce, so the taper length should be at least 5 to 8 times longer than the characteristic dimension of the smallest of the elements to be impedance-matched. In this example, the taper length of the transition 108 should be 5-8 times longer than the width of the conductive strip 106. The flare of the transition member 108 may be achieved by causing the top and bottom surfaces 108A, 108C to diverge from each other along the length of the transition member 108 (i.e., the top and bottom surfaces 108A, 108C are not parallel to each other), and/or by causing the vertical members 108B, 108D to diverge from each other along the length of the transition member 108 (i.e., the vertical members 108B, 108D are not parallel to each other).

The waveguide 110 is coupled to the distal end of the transition member 108 and has an approximately uniform vertical cross-sectional area along the length of the waveguide 110. The waveguide 110 is useful to carry EM signals from the transition member 108 to the horn antenna 112, meaning that the waveguide 110 is useful to traverse a portion of the length or width of the package 100 to facilitate provision of the EM signals to the horn antenna 112. In an application where the EM signals are to traverse a long distance within a package, use of a rectangular waveguide such as waveguide 110 mitigates cross-talk and electromagnetic interference (EMI) effects. The advantage of the waveguide 110 is that the EM signal is fully isolated except at the ends of the waveguide 110. In addition, the waveguide 110 should be formed so the cutoff frequency of the EM mode that is being used to transport the signal is above the frequency of operation of the device. In an example, the mode used is the TE10 waveguide mode and the cutoff frequency is defined by the width of the waveguide. Thus, the width of the waveguide must be such that the cutoff frequency is above the frequency of operation, or else the operational integrity of the waveguide 110 will be compromised. In examples, the waveguide 110 has an impedance of 200 ohms, thus matching the impedance of the distal end of the transition member 108. Because the physical properties of the waveguide 110 are consistent along the length of the waveguide 110, the impedance of the waveguide 110 is also consistent along the length of the waveguide 110. Thus, if the impedance of the waveguide 110 is 200 ohms, the impedance of the proximal end of the horn antenna 112 must also be 200 ohms, or inefficiencies will result, such as those described above. The proximal end of the horn antenna 112 is impedance matched to the waveguide 110 (e.g., 200 ohms). The impedance of free space is 377 ohms, and thus the horn antenna 112 has a flared shape that provides an impedance gradient of 200 ohms at the proximal end of the horn antenna 112 to 377 ohms at the distal end of the horn antenna 112. The physical properties of the horn antenna 112 are the same as those described above for the transition member 108, and thus are not repeated here.

In examples, the conductive strip 106 is composed entirely of electroplated metal, such as copper, aluminum, nickel, or gold. In examples, the transition member 108, the waveguide 110, and the horn antenna 112 comprise electroplated metal, such as copper, aluminum, nickel, or gold, with an interior space that is filled with mold compound (e.g., an epoxy). The conductive strip 106, the transition member 108, the waveguide 110, and the horn antenna 112 comprise low-conductivity metals to avoid ohmic losses, as poor conductors with higher resistivities will produce greater signal losses.

The conductive member 102 has a horizontal cross-sectional area ranging from 2000 um² to 50,000 um², with an area lower than this range being disadvantageous because it could introduce high inductance which could be difficult to impedance match, and with an area above this range being disadvantageous because it could cause the semiconductor die to become unacceptably large. The length of the conductive member 102 ranges from 30 um to 100 um, with a length lower than this range being impossible to manufacture, and with a length above this range being disadvantageous because of high inductance levels. The metals used for the structures described above (in FIG. 1A) must have a very low resistivity. Typically, this material is copper, but other materials may be useful, such as aluminum, silver, gold, platinum, etc. Although the EM wave travels in the dielectric material, the EM fields are induced by currents that are flowing in the metal structures. In particular, at high frequencies, due to the skin effect, these currents flow in the external surface of these metallic parts. Thus, low resistivity in the metals is necessary.

FIG. 1B is a frontal view of the semiconductor package 100, in accordance with various examples. FIG. 1C is a profile cross-sectional view of the semiconductor package 100, in accordance with various examples. FIG. 1D is a top-down, see-through view of the semiconductor package 100, in accordance with various examples.

The metal structures shown in FIGS. 1A-1D—specifically, the conductive member 102, the conductive strip 106, the waveguide 110, and the horn antenna 112—and a mold compound or other dielectric film covering and/or filling these metal structures together constitute a multi-layer package substrate. A multi-layer package substrate is defined as a substrate of a semiconductor package, where the substrate includes multiple metal layers formed by electroplating and that further includes a dielectric such as a mold compound or film (e.g., AJINOMOTO® build-up film (ABF)) filling spaces between and around the multiple metal layers. The multiple metal layers form a network to route signals and/or power between various locations within the package 100. A multi-layer package substrate differs from a printed circuit board (PCB) because the multi-layer package substrate is within the semiconductor package 100, whereas the PCB is outside the semiconductor package 100. The multi-layer package substrate includes multiple metal layers that are separated by a solid, tangible dielectric, whereas the PCB may contain multiple layers of printed circuit board that may not be separated by a dielectric material other than air. Accordingly, FIGS. 2A-2F provide various views of such a multi-layer package substrate within the semiconductor package 100, in accordance with various examples.

FIG. 2A is a perspective view of the molded semiconductor package 100 having a directional antenna and efficient signal path included therein, in accordance with various examples. The structure of FIG. 2A is identical to that of FIG. 1A, except that a mold compound 200 is expressly shown. In examples, the mold compound 200 may be substituted with a dielectric film, such as ABF as described above. This discussion assumes the use of the mold compound 200, but a dielectric film or other material may be used. The mold compound 200 covers the semiconductor die 98, the conductive strip 106, the transition member 108, the waveguide 110, and the horn antenna 112. The mold compound 200 may also be present inside the transition member 108, the waveguide 110, and/or the horn antenna 112. The dielectric constant of the mold compound 200 or a substitute material (e.g., ABF) used in lieu of the mold compound 200 ranges from 2.4 to 4, with a dielectric constant below this range being disadvantageous because internal metallic features will grow in size, and with a dielectric constant above this range being disadvantageous because as dielectric constant increases the loss tangent also increases, making the package unacceptably lossy. FIG. 2B is a frontal view of the semiconductor package 100, in accordance with various examples. FIG. 2C is a profile view of the semiconductor package 100, in accordance with various examples. FIG. 2D is a top-down, see-through view of the semiconductor package 100, in accordance with various examples.

In examples, the various metal structures of the semiconductor package 100 are electroplated (e.g., copper, nickel, aluminum, gold). These structures may be monolithic layers of electroplated metal. For example, as shown in FIG. 2A, vertical member 110B may be a monolithic layer of electroplated metal. In other examples, the vertical member 110B, like other vertical members of the semiconductor package 100, includes an array of metal vias. FIG. 2E is a perspective view of the semiconductor package 100 having vertical members formed by such metal vias 250. The metal vias 250 are touching, such that each metal via 250 is in contact with at least one other metal via 250. To prevent leakage of EM signals and the resulting inefficiencies, the metal vias 250 are in contact with each other such that no gaps are present between the metal vias 250. In FIG. 2E, the metal vias 250 are shown to be cylindrical, but any via shape may be useful. FIG. 2F is a profile view of the semiconductor package 100 having the metal vias 250, in accordance with various examples.

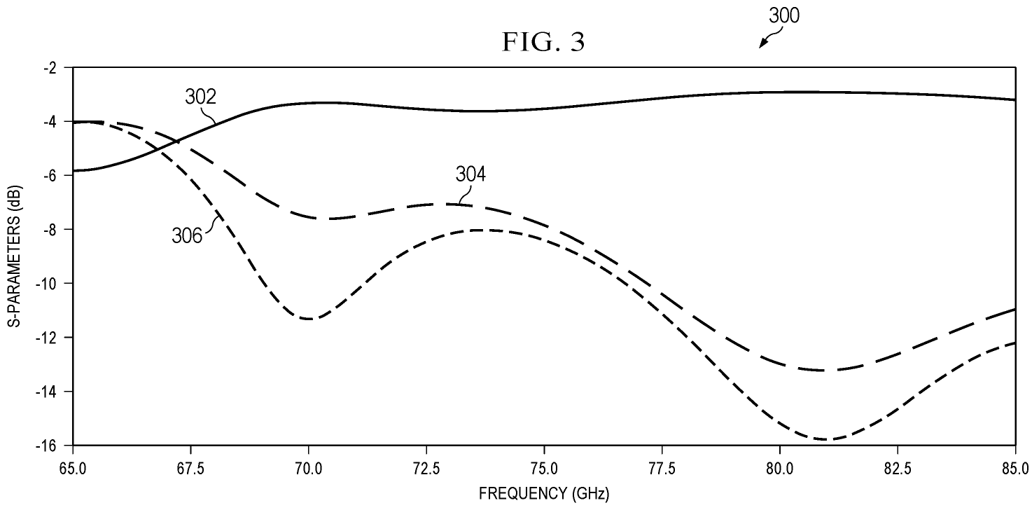

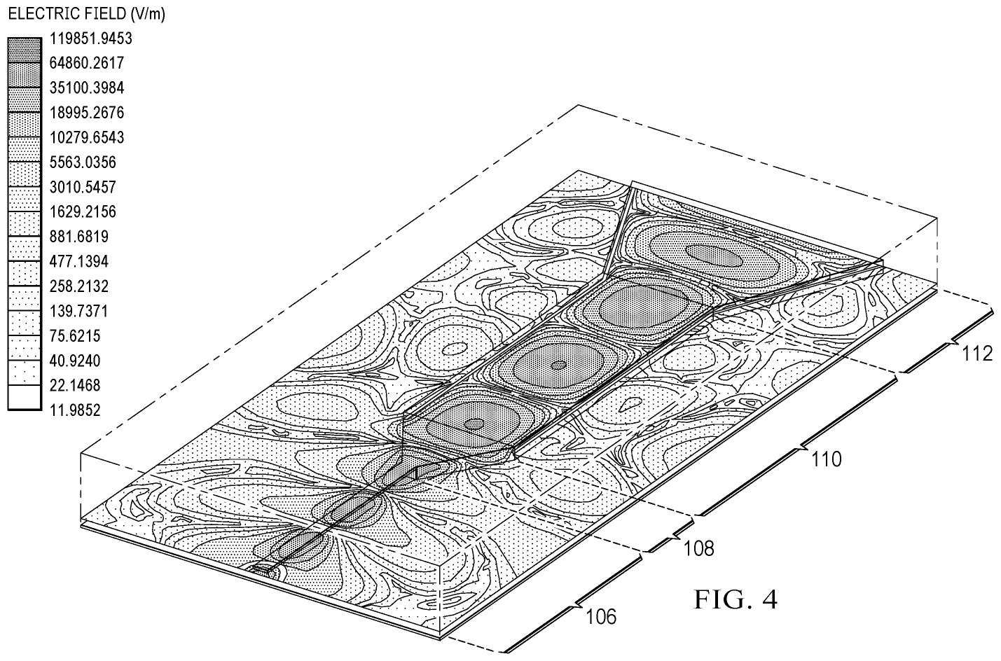

FIG. 3 is a graph 300 depicting the efficiency of a molded semiconductor package having a directional antenna and efficient signal path included therein, such as the semiconductor package 100, in accordance with various examples. The x-axis depicts frequency in gigahertz (GHz) and the y-axis depicts S-parameters in decibels (dB). A curve 302 depicts the insertion losses associated with energy propagating from the proximal end of the conductive strip 106 to the distal end of the horn antenna 112. As shown, at approximately 65 GHz, the curve 302 has an insertion loss (S12) of approximately −5.8 dB, and this value approaches approximately S12=−3 dB at higher frequencies. A curve 304 depicts return losses associated with energy propagating from the proximal end of the conductive strip 106 to the distal end of the horn antenna 112, specifically, the degree of energy reflected back toward the proximal end of the conductive strip 106. As shown, at approximately 65 GHz, the curve 304 has a return loss of approximately 511=−4 dB, but at higher frequencies, such as around 81 GHz, the curve 304 gain approaches −13 dB. A curve 306 depicts return losses associated with energy propagating from the distal end of the horn antenna 112 toward the proximal end of the conductive strip 106, specifically, the degree of energy reflected back toward the distal end of the horn antenna 112. As shown, at approximately 65 GHz, the curve 306 has a return loss of approximately S22=−4 dB, but at higher frequencies, such as around 81 GHz, the curve 306 S22 approaches −15.8 dB. Overall, performance improves as frequency of operation increases, and thus a desirable operation bandwidth for the semiconductor package 100 may range from approximately 78 GHz to 85 GHz.

FIG. 4 is a perspective view of an electric field diagram depicting the efficiency of a molded semiconductor package having a directional antenna and efficient signal path included therein, in accordance with various examples. The electric field diagram includes multiple segments marked with numerals according to the metal structures of the semiconductor package 100 to which they correspond. For example, the segment marked 106 corresponds to the conductive strip 106; the segment marked 108 corresponds to the transition member 108; the segment marked 110 corresponds to the waveguide 110; and the segment marked 112 corresponds to the horn antenna 112. The segment of the electric field diagram for the conductive strip 106 shows that the strength of the electric field is concentrated (strongest) within the conductive strip 106 and dissipates laterally from the conductive strip 106. Some of the electric field extends laterally beyond the conductive strip 106.

The segment of the electric field diagram for the transition member 108 also shows that the strength of the electric field is concentrated (strongest) within the transition member 108 and dissipates laterally from the transition member 108. However, the transition member 108 is formed by electroplating to produce the specific structure described above, with solid vertical members 108B, 108D that are not susceptible to energy loss, and further with space within the transition member 108 that is filled with mold compound or another suitable material (e.g., ABF film). Accordingly, the amount of energy loss laterally is less compared to that of the conductive strip 106, as shown, and less compared to that of signal-carrying metal structures that are formed differently than the transition member 108.

The segment of the electric field diagram for the waveguide 110 shows that the strength of the electric field is concentrated (strongest) within the waveguide 110 and dissipates laterally from the waveguide 110. However, the waveguide 110 is formed by electroplating to produce the specific structure described above, with solid vertical members 110B, 110D that are not susceptible to energy loss, and further with space within the waveguide 110 that is filled with mold compound or another suitable material (e.g., ABF film). Accordingly, the amount of energy loss laterally is less compared to that of the conductive strip 106, as shown, and less compared to that of signal-carrying metal structures that are formed differently than the waveguide 110.

The segment of the electric field diagram for the horn antenna 112 shows that the strength of the electric field is concentrated (strongest) within the horn antenna 112 and dissipates laterally from the horn antenna 112. However, the horn antenna 112 is formed by electroplating to produce the specific structure described above, with solid vertical members 112B, 112D that are not susceptible to energy loss, and further with space within the horn antenna 112 that is filled with mold compound or another suitable material (e.g., ABF film). Accordingly, the amount of energy loss laterally is less compared to that of the conductive strip 106, as shown, and less compared to that of signal-carrying metal structures that are formed differently than the horn antenna 112.

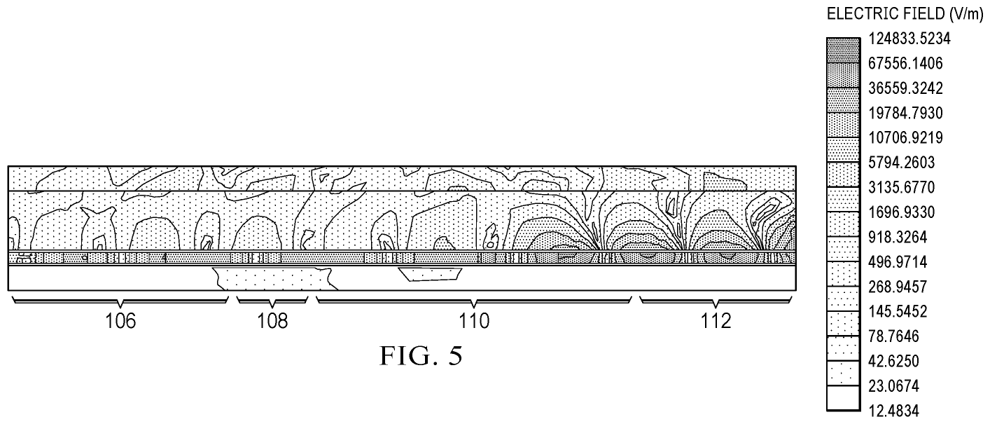

FIG. 5 is a profile view of an electric field diagram depicting the efficiency of a molded semiconductor package having a directional antenna and efficient signal path included therein, such as the semiconductor package 100, in accordance with various examples. As in FIG. 4, the numerals 106, 108, 110, and 112 correspond to the vertical electric field profiles of the conductive strip 106, the transition member 108, the waveguide 110, and the horn antenna 112, respectively. The electric field diagram of FIG. 5 shows that the specific structures of the conductive strip 106, the transition member 108, the waveguide 110, and the horn antenna 112 limit energy inefficiencies by preventing significant vertical energy loss as EM waves propagate toward and through the horn antenna 112. Although vertical energy loss in the distal segment of the waveguide 110 and in the horn antenna 112 is more significant than in the conductive strip 106, the transition member 108, and the proximal segment of the waveguide 110, the energy loss is still significantly less than would be experienced with structures different than those described herein.

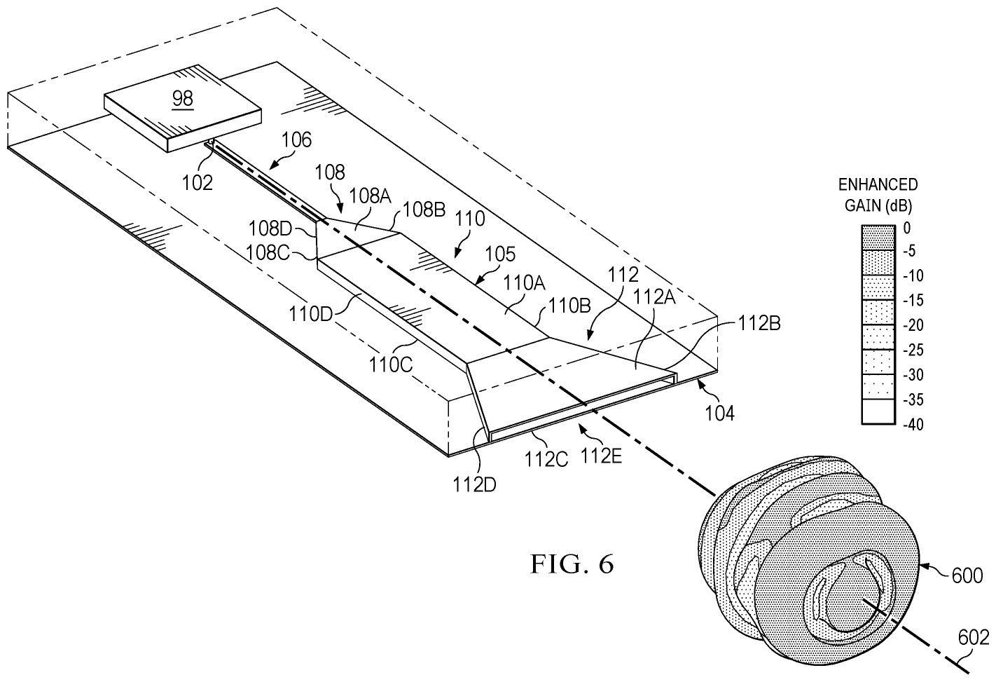

FIG. 6 is a schematic diagram depicting the directionality of an antenna in a molded semiconductor package, such as the semiconductor package 100, in accordance with various examples. Specifically, FIG. 6 depicts EM waves 600 propagating from the horn antenna 112 into free space outside the semiconductor package 100. The shading of the EM wave 600 demonstrates enhanced gain along the axis 602 as the EM wave 600 propagates away from the horn antenna 112, and, further, the EM wave 600 shows little or no propagation laterally from the axis 602. Accordingly, the EM wave 600 demonstrates high directionality along the axis 602.

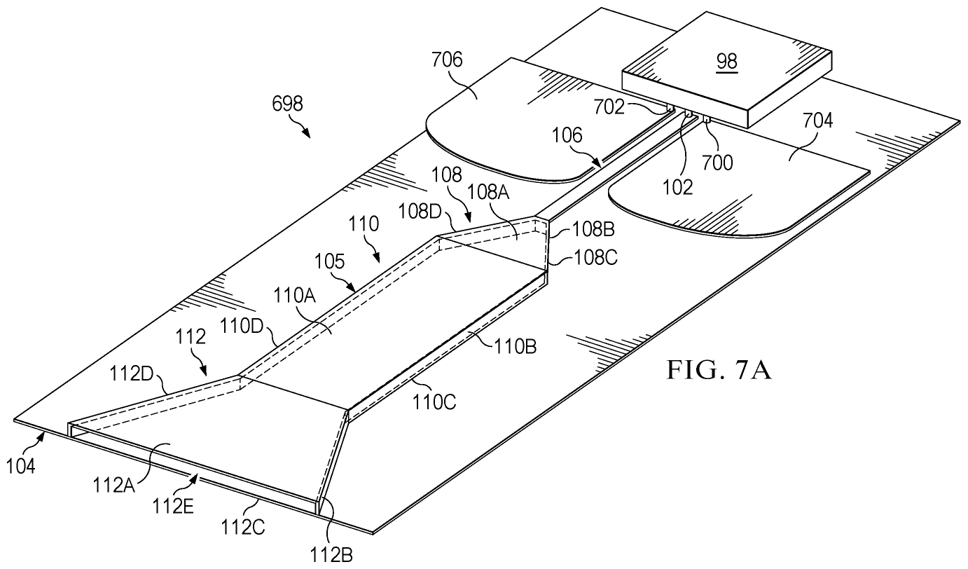

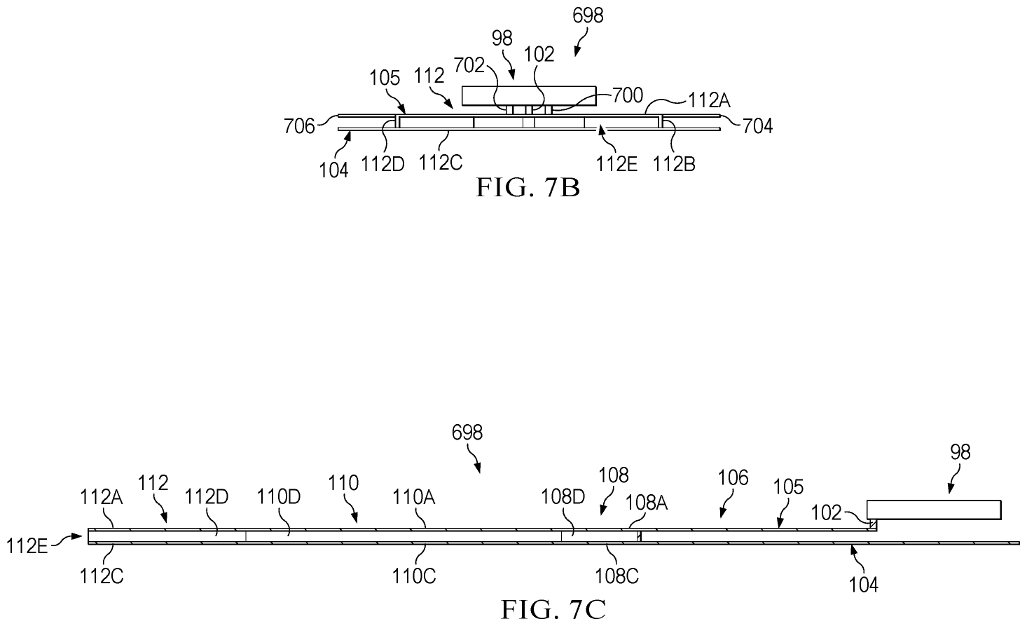

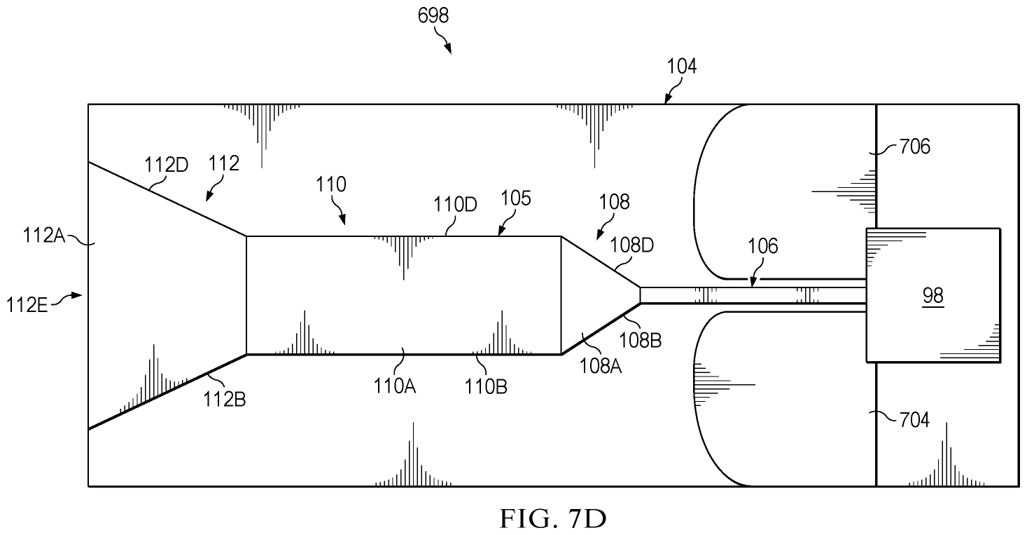

FIG. 7A is a perspective view of a molded semiconductor package 698 having a directional antenna, efficient signal path, and grounded coplanar waveguide included therein, in accordance with various examples. More particularly, semiconductor package 698 of FIG. 7A is identical in structure to the semiconductor package 100 described above, except that the semiconductor package 698 includes a conductive member 700 coupled to a grounded coplanar waveguide (GCPW) 704 and a conductive member 702 coupled to a grounded coplanar waveguide (GCPW) 706. Each of the conductive members 700, 702 is coupled to a ground connection within the semiconductor die 98, and each of the GCPWs 704, 706 is coupled to ground by coupling to the first horizontal metal layer 104 (the ground plane). In examples, the lateral edges of the GCPWs 704, 706, which are laterally the most distal from the conductive strip 106, extend downward to couple to the first horizontal metal layer 104, although any portion of the GCPWs 704, 706 may be coupled to the first horizontal metal layer 104. Further, the GCPWs 704, 706 may comprise any suitable metal (e.g., copper, aluminum, nickel, gold) and may be formed using, e.g., an electroplating process. In addition, the GCPWs 704, 706 may have any suitable shape, and the scope of this disclosure is not limited to the specific shapes shown in FIG. 7A. FIG. 7B is a frontal view of the semiconductor package 698, in accordance with various examples. FIG. 7C is a profile cross-sectional view of the semiconductor package 698, in accordance with various examples. FIG. 7D is a top-down, see-through view of the semiconductor package 698, in accordance with various examples.

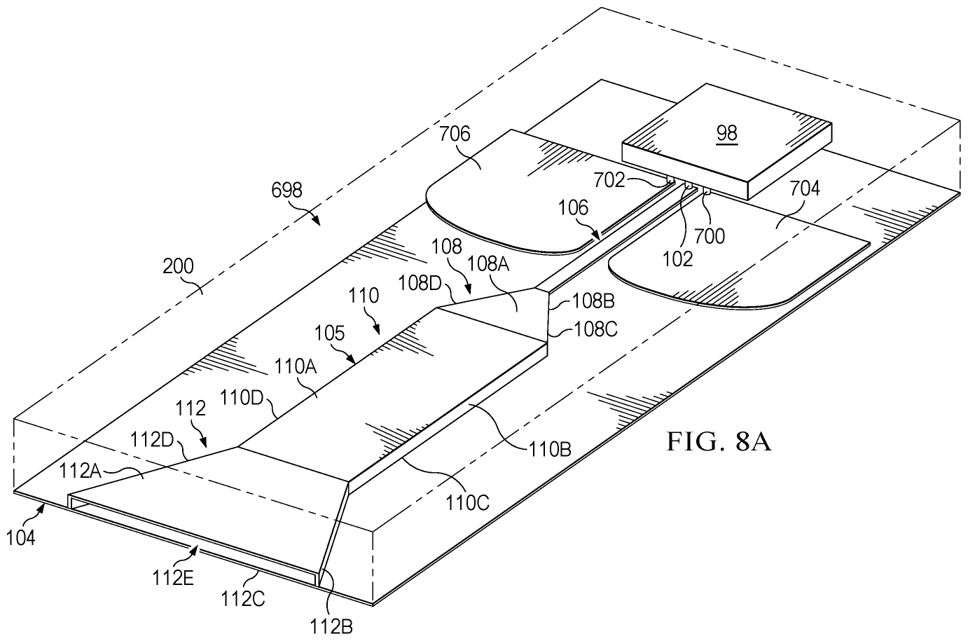

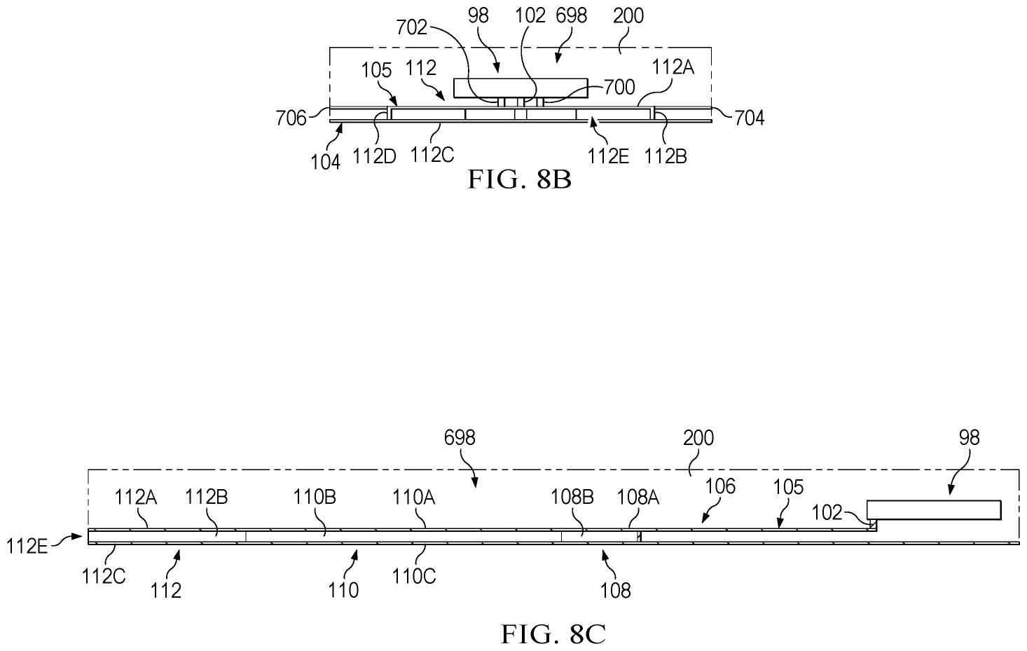

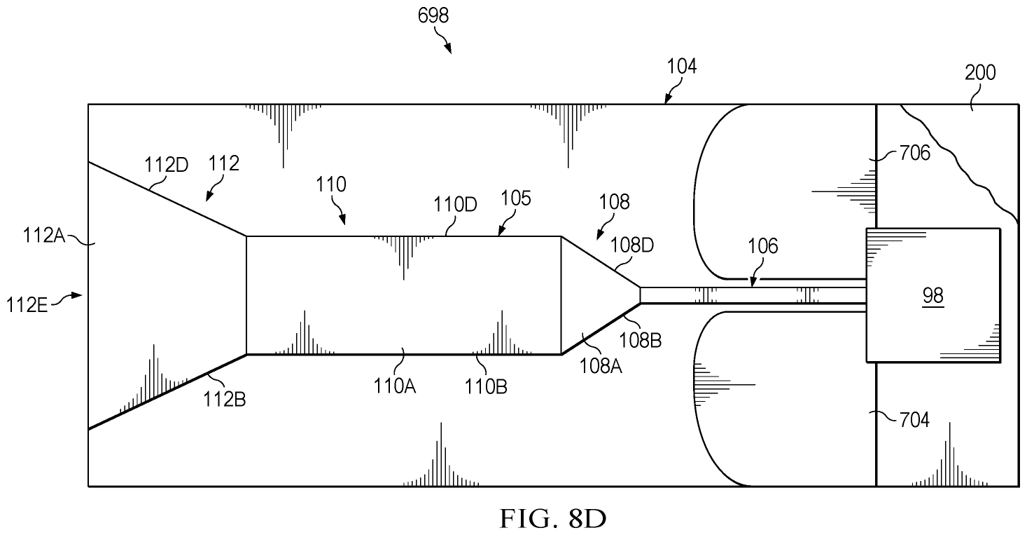

FIG. 8A is a perspective view of the semiconductor package 698 having an insulative material covering the semiconductor die 98 and the various depicted metal structures of the semiconductor package 698, including the GCPWs 704, 706, such as the mold compound 200, in accordance with various examples. As described above, a film, such as ABF, may be used in lieu of the mold compound 200. Other materials are also contemplated and included in the scope of this disclosure. FIG. 8B is a frontal view of the semiconductor package 698, in accordance with various examples. FIG. 8C is a profile cross-sectional view of the semiconductor package 698, in accordance with various examples. FIG. 8D is a top-down, see-through view of the semiconductor package 698, in accordance with various examples.

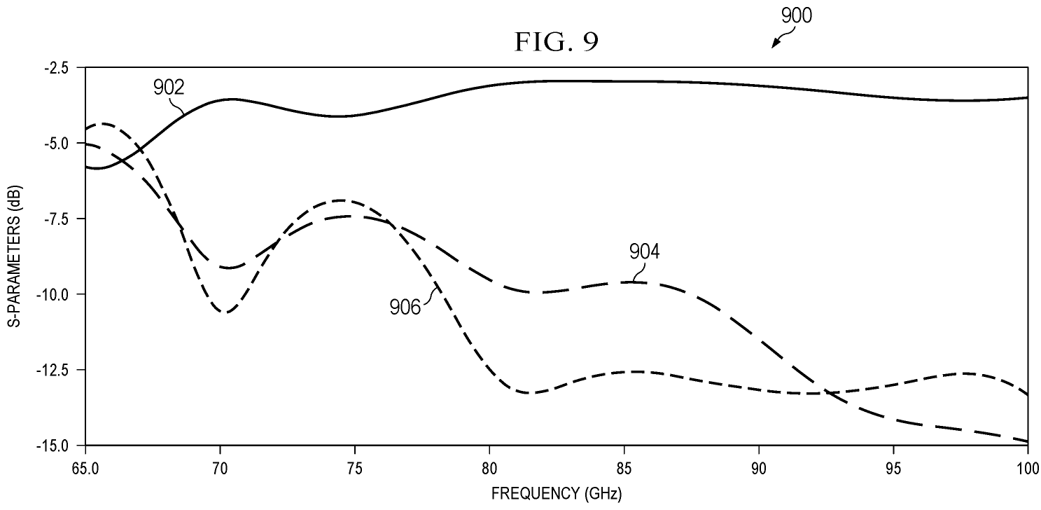

FIG. 9 is a graph 900 depicting the efficiency of a molded semiconductor package having a directional antenna, efficient signal path, and grounded coplanar waveguide included therein, in accordance with various examples. The x-axis depicts frequency in gigahertz (GHz) and the y-axis depicts S-parameters in decibels (dB). A curve 902 depicts the insertion losses associated with energy propagating from the proximal end of the conductive strip 106 to the distal end of the horn antenna 112. As shown, at approximately 65 GHz, the curve 902 has an insertion loss S12 of approximately −5.8 dB, and S12 approaches approximately −3 dB at higher frequencies. A curve 904 depicts return losses associated with energy propagating from the proximal end of the conductive strip 106 to the distal end of the horn antenna 112, specifically, the degree of energy reflected back toward the proximal end of the conductive strip 106. As shown, at approximately 65 GHz, the curve 904 has a return loss S11 of approximately −5 dB, but at higher frequencies, such as around 100 GHz, the curve 904 S11 approaches −15 dB. A curve 906 depicts return losses associated with energy propagating from the distal end of the horn antenna 112 toward the proximal end of the conductive strip 106, specifically, the degree of energy reflected back toward the distal end of the horn antenna 112. As shown, at approximately 65 GHz, the curve 906 has a return loss S22 of approximately −4.5 dB, but at higher frequencies, such as around 100 GHz, the curve 906 S22 approaches −13 dB. Overall, performance improves as frequency of operation increases, and thus a desirable operation bandwidth for the semiconductor package 100 may range from approximately 90 GHz to 100 GHz.

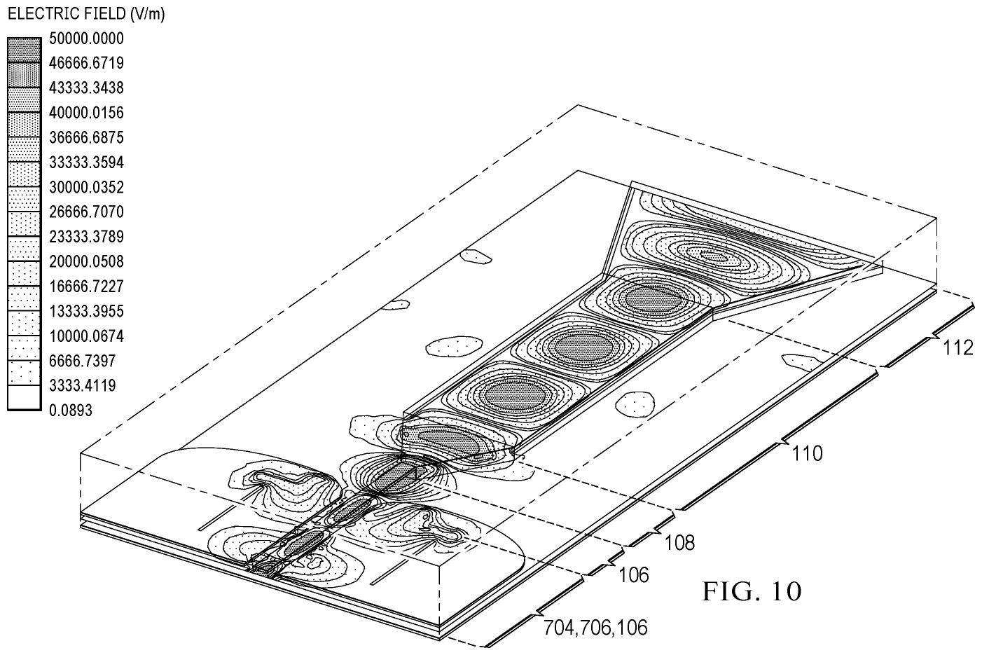

FIG. 10 is a perspective view of an electric field diagram depicting the efficiency of the semiconductor package 698, in accordance with various examples. The electric field diagram includes multiple segments marked with numerals according to the metal structures of the semiconductor package 698 to which they correspond. For example, the segment marked 106, 704, 706 corresponds to the conductive strip 106, the GCPW 704, and the GCPW 706; the segment marked only 106 corresponds to the conductive strip 106; the segment marked 108 corresponds to the transition member 108; the segment marked 110 corresponds to the waveguide 110; and the segment marked 112 corresponds to the horn antenna 112. The segment of the electric field diagram for the conductive strip 106 and the GCPWs 704, 706 shows that the strength of the electric field is concentrated (strongest) within the conductive strip 106 and dissipates laterally from the conductive strip 106. Some of the electric field extends laterally beyond the conductive strip 106, but the degree of lateral energy leakage is reduced due to the presence of the GCPWs 704, 706.

The segment of the electric field diagram solely for the conductive strip 106 shows that the strength of the electric field is concentrated (strongest) within the conductive strip 106 and dissipates laterally from the conductive strip 106. Some of the electric field extends laterally beyond the conductive strip 106.

The segment of the electric field diagram for the transition member 108 also shows that the strength of the electric field is concentrated (strongest) within the transition member 108 and dissipates laterally from the transition member 108. However, the transition member 108 is formed by electroplating to produce the specific structure described above, with solid vertical members 108B, 108D that are not susceptible to energy loss, and further with space within the transition member 108 that is filled with mold compound or another suitable material (e.g., ABF film). Accordingly, the amount of energy loss laterally is less compared to that of the conductive strip 106, as shown, and less compared to that of signal-carrying metal structures that are formed differently than the transition member 108.

The segment of the electric field diagram for the waveguide 110 shows that the strength of the electric field is concentrated (strongest) within the waveguide 110 and dissipates laterally from the waveguide 110. However, the waveguide 110 is formed by electroplating to produce the specific structure described above, with solid vertical members 110B, 110D that are not susceptible to energy loss, and further with space within the waveguide 110 that is filled with mold compound or another suitable material (e.g., ABF film). Accordingly, the amount of energy loss laterally is less compared to that of the conductive strip 106, as shown, and less compared to that of signal-carrying metal structures that are formed differently than the waveguide 110.

The segment of the electric field diagram for the horn antenna 112 shows that the strength of the electric field is concentrated (strongest) within the horn antenna 112 and dissipates laterally from the horn antenna 112. However, the horn antenna 112 is formed by electroplating to produce the specific structure described above, with solid vertical members 112B, 112D that are not susceptible to energy loss, and further with space within the horn antenna 112 that is filled with mold compound or another suitable material (e.g., ABF film). Accordingly, the amount of energy loss laterally is less compared to that of the conductive strip 106, as shown, and less compared to that of signal-carrying metal structures that are formed differently than the horn antenna 112.

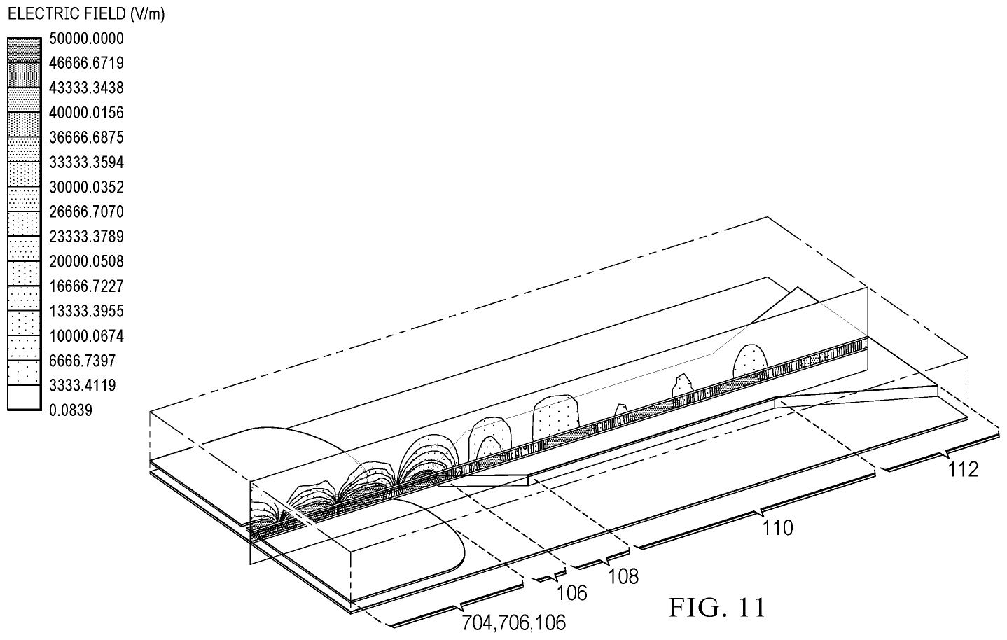

FIG. 11 is a perspective view of an electric field diagram depicting the efficiency of the semiconductor package 698, in accordance with various examples. The numerals 106, 704, and 706; 106; 108; 110; and 112 correspond to the conductive strip 106 along with the GCPWs 704, 706, the conductive strip 106 alone, the transition member 108, the waveguide 110, and the horn antenna 112, respectively. The electric field diagram of FIG. 11 is taken along the axial midline of the metal structures shown in FIG. 11, and thus does not reflect electric field activity in areas outside of the axial midline. The electric field diagram shows that the specific structures of the conductive strip 106, the transition member 108, the waveguide 110, and the horn antenna 112 limit energy inefficiencies (relative to a semiconductor package that does not implement the specific metal structures described herein) by preventing significant vertical energy loss as EM waves propagate toward and through the horn antenna 112.

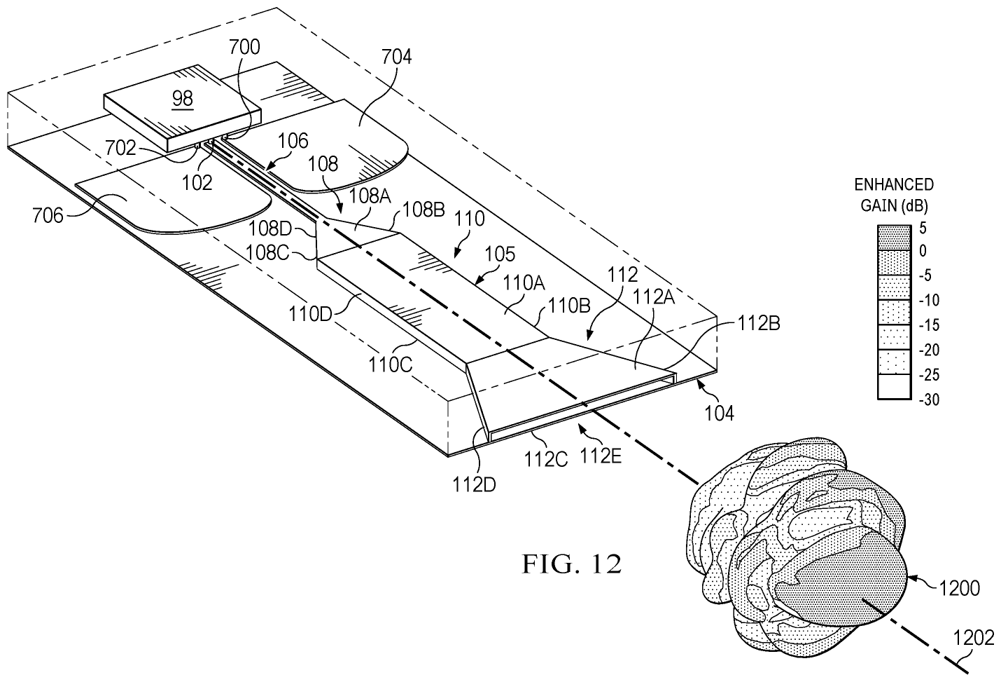

FIG. 12 is a schematic diagram depicting the directionality of an antenna in the semiconductor package 698, in accordance with various examples. Specifically, FIG. 12 depicts EM waves 1200 propagating from the horn antenna 112 into free space outside the semiconductor package 698. The shading of the EM wave 1200 demonstrates enhanced gain along the axis 1202 as the EM wave 1200 propagates away from the horn antenna 112, and, further, the EM wave 1200 shows little or no propagation laterally from the axis 1202. Accordingly, the EM wave 1200 demonstrates high directionality along the axis 1202.

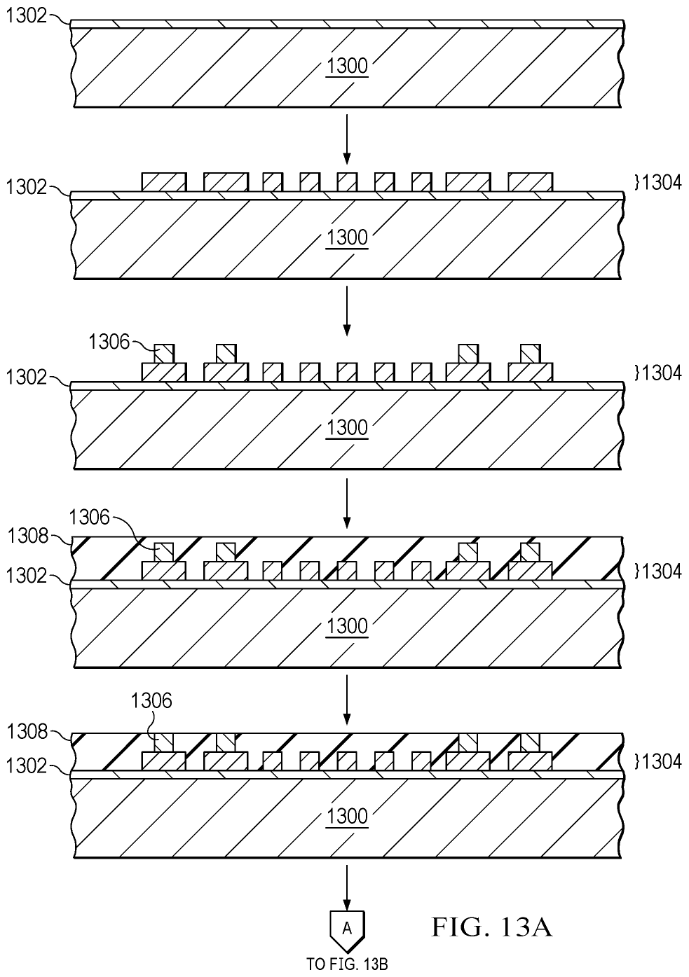

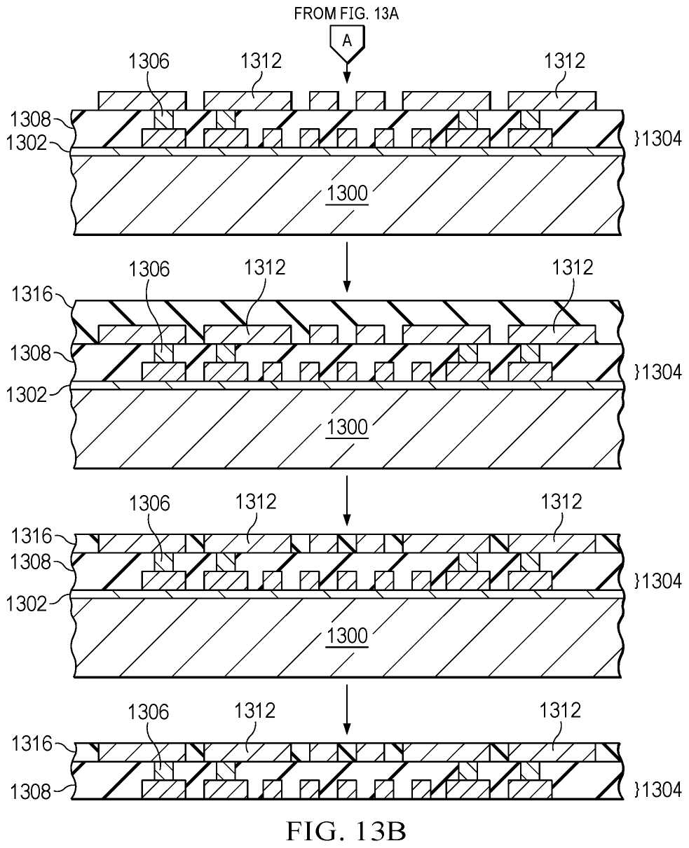

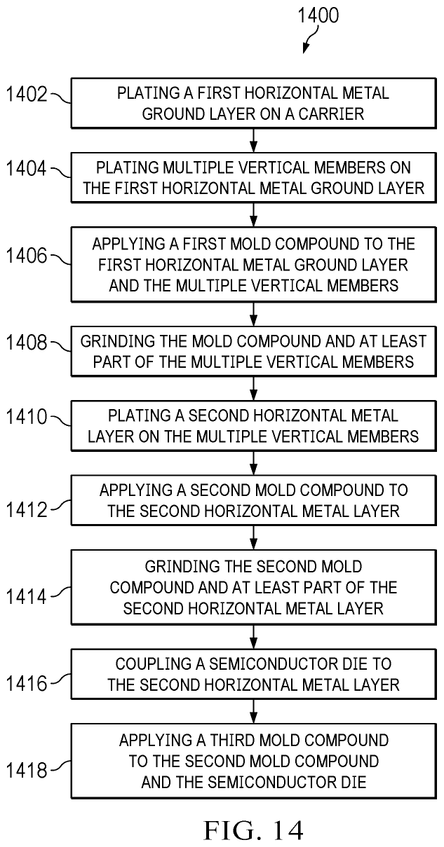

FIGS. 13A and 13B are a process flow diagram of a method for manufacturing a semiconductor package having a directional antenna and efficient signal path included therein, in accordance with various examples. Although the process flow of FIGS. 13A-13B does not depict the actual manufacture of the specific metal structures of the semiconductor packages 100, 698, the process flow of FIGS. 13A-13B does depict the manufacturing technique by which the metal structures of the semiconductor packages 100, 698 are formed. FIG. 14 is a flow diagram of a method 1400 for manufacturing a semiconductor package having a directional antenna and efficient signal path include therein, in accordance with various examples. Accordingly, FIGS. 13A-13B and 14 are described in parallel. The process flow begins with the provision of a metal carrier 1300 having an electroplating seed layer 1302 (e.g., copper) deposited thereupon. The process flow then includes electroplating a metal layer 1304 on the metal carrier 1300. Any suitable metal may be used, such as copper, aluminum, nickel, or gold, for example. The metal layer 1304 may have any shape, size, or configuration. For example, the metal layer 1304 may have the form of the first horizontal metal layer 104, described above. As FIG. 14 depicts, the method 1400 begins with plating a first horizontal metal ground layer on a carrier (1402).

The process flow of FIGS. 13A-13B then includes electroplating vertical members 1306 on the metal layer 1304. Any suitable metal may be used, such as copper, aluminum, nickel, or gold, for example. The vertical members 1306 may have any shape, size, or configuration. For example, the vertical members 1306 may have the form of the vertical members described above, such as vertical members 108B, 108D, 110B, 110D, 112B, and 112D. As FIG. 14 depicts, the method 1400 includes plating multiple vertical members on the first horizontal metal ground layer (1404).

The process flow of FIGS. 13A-13B then includes applying a mold compound 1308 or other suitable insulative material (e.g., ABF film), although this description assumes the application of a mold compound. As FIG. 14 depicts, the method 1400 includes applying a first mold compound to the first horizontal metal ground layer and the multiple vertical members (1406).

The process flow of FIGS. 13A-13B includes grinding the mold compound 1308, for example, until a top surface of the vertical members 1306 is flush with the top surface of the mold compound 1308. As FIG. 14 depicts, the method 1400 includes grinding the mold compound and at least part of the multiple vertical members (1408).

The process flow of FIGS. 13A-13B includes electroplating another metal layer 1312 (seed layer(s) for any electroplating performed after plating of the metal layer 1304 are not expressly depicted, but should be understood to be applied as needed). Any suitable metal may be used, such as copper, aluminum, nickel, or gold, for example. The metal layer 1312 may have any shape, size, or configuration. For example, the metal layer 1312 may have the form of the second horizontal metal layer 105 as described above. As FIG. 14 depicts, the method 1400 includes plating a second horizontal metal layer on the multiple vertical members (1410).

The process flow of FIGS. 13A-13B includes application of a mold compound 1316 (or another suitable insulative material, such as ABF film) to the metal layer 1312. As FIG. 14 depicts, the method 1400 includes applying a second mold compound to the second horizontal metal layer (1412).

The process flow of FIGS. 13A-13B includes grinding the mold compound 1316 until the top surface of the mold compound 1316 is flush with the top surface of the metal layer 1312 (and removing the carrier 1300). As FIG. 14 shows, the method 1400 includes grinding the second mold compound and at least part of the second horizontal metal layer (1414).

The method 1400 may additionally include coupling a semiconductor die to the second horizontal metal layer (1416) and applying a third mold compound (e.g., the mold compound 200) to the second mold compound and the semiconductor die (1418) to produce the semiconductor package 100 and/or semiconductor package 698 described above.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

Uses of the term “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die;
a conductive member coupled to the semiconductor die; and
a multi-layer package substrate including:
a first horizontal metal layer to provide a ground connection;
a second horizontal metal layer above the first horizontal metal layer;
vertical members coupling to the first and second horizontal metal layers; and
a mold compound covering the first and second horizontal metal layers and the vertical members,
wherein the first horizontal metal layer, the second horizontal metal layer, and the vertical members together form a structure including a conductive strip coupled to the conductive member, a transition member coupled to the conductive strip, a waveguide coupled to the transition member, and a horn antenna coupled to the waveguide.

2. The semiconductor package of claim 1, wherein the transition member has a flared shape that has a first end and a second end narrower than the first end, the second end coupled to the conductive strip and the first end coupled to the waveguide.

3. The semiconductor package of claim 1, wherein the conductive strip, the transition member, the waveguide, and the horn antenna are impedance matched.

4. The semiconductor package of claim 1, wherein the vertical members include first and second monolithic vertical members that form parts of the transition member, the waveguide, and the horn antenna.

5. The semiconductor package of claim 1, wherein the vertical members include a plurality of vias, each via in the plurality of vias in contact with at least one other via in the plurality of vias.

6. The semiconductor package of claim 1, wherein the waveguide is a rectangular prism.

7. The semiconductor package of claim 1, wherein at least some of the mold compound is positioned inside the horn antenna, the waveguide, and the transition member.

8. A semiconductor package, comprising:
a semiconductor die;
a conductive member coupled to the semiconductor die and extending away from the semiconductor die; and
a multi-layer package substrate including:
a first horizontal metal layer to provide a ground connection;
a second horizontal metal layer above the first metal layer;
vertical members coupling to the first and second horizontal metal layers; and
a mold compound contacting portions of the first and second horizontal metal layers and the vertical members,
wherein:
the first horizontal metal layer forms a conductive strip coupled to the conductive member and configured to guide an electromagnetic wave away from the conductive member;
the first and second horizontal metal layers and the vertical members form a transition member coupled to the conductive strip, having a flared shape, and configured to guide the electromagnetic wave away from the conductive strip,
the first and second horizontal metal layers and the vertical members form a waveguide coupled to the transition member, having a rectangular prism shape, and configured to guide the electromagnetic wave away from the transition member,
the first and second horizontal metal layers and the vertical members form a horn antenna coupled to the waveguide and configured to direct the electromagnetic wave from the waveguide to a predetermined direction.

9. The semiconductor package of claim 8, wherein the transition member comprises a first end coupled to the conductive strip and a second end coupled to the waveguide, the first end narrower than the second end.

10. The semiconductor package of claim 8, wherein the conductive strip, the transition member, and the waveguide, and the horn antenna are impedance matched.

11. The semiconductor package of claim 8, wherein the vertical members include monolithic vertical members that form parts of the transition member, the waveguide, and the horn antenna.

12. The semiconductor package of claim 8, wherein the vertical members comprise a plurality of vias, each via in the plurality of vias in contact with at least one other via in the plurality of vias.

13. The semiconductor package of claim 8, wherein at least some of the mold compound is positioned inside the horn antenna, the waveguide, and the transition member.

14. A method for manufacturing a semiconductor package, comprising:
forming a multi-layer package substrate by:
plating a first horizontal metal ground layer on a carrier;
plating multiple vertical members on the first horizontal metal ground layer;
applying a first mold compound to the first horizontal metal ground layer and the multiple vertical members;
grinding the mold compound and at least part of the multiple vertical members;
plating a second horizontal metal layer on the multiple vertical members;
applying a second mold compound to the second horizontal metal layer; and
grinding the second mold compound and at least part of the second horizontal metal layer;
coupling a semiconductor die to the second horizontal metal layer; and
applying a third mold compound to the second mold compound and the semiconductor die,
wherein the first horizontal metal ground layer, the multiple vertical members, and the second horizontal metal layer form a structure that includes a conductive strip coupled to the semiconductor die and multiple impedance-matched components of differing shapes configured to guide electromagnetic waves in a predetermined direction.

15. The method of claim 14, wherein plating the multiple vertical members comprises plating a plurality of vias, each via in the plurality of vias in contact with another via in the plurality of vias.

16. The method of claim 14, wherein plating the multiple vertical members includes plating a monolithic vertical member, the multiple impedance-matched components including the monolithic vertical member.

17. The method of claim 14, wherein the multiple impedance-matched components of differing shapes comprise a transition member having a flared shape, a waveguide, and a horn antenna.

18. The method of claim 17, wherein the transition member having the flared shape has a first end coupled to the conductive strip and a second end coupled to the waveguide, the second end wider than the first end.

19. The method of claim 17, wherein the waveguide is shaped as a rectangular prism.

20. The method of claim 14, further comprising forming a grounded coplanar waveguide having first and second components, the conductive strip positioned in between the first and second components.
